(19) United States
(12) Patent Application Publication
(10) Pub. No.: US 2021/0332292 A1
(43) Pub. Date: Oct. 28, 2021

(54) PEROVSKITE MICROSPHERE MATERIAL, MIXED-COLOR LIGHT CONVERSION FILM, AND DISPLAY

(71) Applicant: Shenzhen China Star Optoelectronics Semiconductor Display Technology Co., Ltd., Shenzhen (CN)

(72) Inventor: Zhiping Hu, Shenzhen (CN)

(73) Assignee: Shenzhen China Star Optoelectronics Semiconductor Display Technology Co., Ltd., Shenzhen (CN)

(21) Appl. No.: 16/625,828

(22) PCT Filed: Dec. 13, 2019
(86) PCT No.: PCT/CN2019/125038

§ 371 Date: Dec. 23, 2019

(30) Foreign Application Priority Data
Nov. 27, 2019 (CN) 201911184389.9

(51) Int. Cl. C09K 11/66; H01L 51/50; H01L 51/56; H01L 51/00; C09K 11/02

(52) U.S. Cl. CPC C09K 11/665; H01L 51/5036; C09K 11/025; H01L 51/0077; H01L 51/56

(57) ABSTRACT

The present invention provides a perovskite microsphere material, a mixed-color light conversion film, preparation methods thereof, and a display. By using the red and green perovskite microspheres with the encapsulating structure provided by the present invention as an optical conversion material of the white OLED display, the photon utilization of organic light-emitting materials can be improved, display power consumption is reduced, and thus process difficulty and cost are decreased.

### BACKGROUND OF INVENTION

The present application claims priority to Chinese patent application no. 201911184389.9 submitted to Chinese Patent Office on Nov. 27, 2019, entitled “Perovskite Microsphere Material, Mixed-Color Light Conversion Film, and Display”, the entire contents of which are incorporated herein by reference.

### FIELD OF INVENTION

The present invention relates to a field of display technology, and in particular, to a simple and efficient display structure.

### DESCRIPTION OF PRIOR ART

Down-conversion white organic light-emitting diode (OLED) displays use blue light OLEDs to excite green and red light conversion layers to produce green light and red light, which are mixed with the transmitted blue light to form white light. Compared to a conventional method of preparing pixelated OLED displays or OLED displays that cause white light to pass through a color filter to generate white light, structures of such down-conversion white OLED displays are relatively simple. In order to improve the color purity and color gamut of such down-conversion white OLEDs, there is a need to develop light conversion materials with high light-emitting efficiency, narrow emission peaks, and wide color gamuts.

In recent years, perovskite materials have attracted much attention due to their advantages, such as adjustable band gaps, narrow emission peaks, high quantum efficiency, and wide color gamut, and they have been rapidly developed in a field of light-emitting displays due to their excellent optical characteristic. Since the fluorescence quantum yield of the perovskite materials has closed to 99%, the external quantum efficiency of light-emitting diodes using the perovskite materials has exceeded 20%. In addition, the perovskite crystals have high absorption coefficients for a blue light wavelength band, and the perovskite materials can be used as excellent light conversion materials. However, perovskite structures have a disadvantage of water and oxygen sensitivity, which makes the stability of devices based on these materials a major problem, thereby preventing the perovskite materials from being widely applied in the field of light-emitting displays.

Accordingly, development of a highly stable perovskite material has become a key technology for the industrial application of this material.

### SUMMARY OF INVENTION

An object of the present invention is to provide a white organic light-emitting diode (OLED) display with high stability. Therefore, the present invention develops red and green perovskite microspheres each with an encapsulating structure, which have advantages of a high light-emitting efficiency, narrow spectrum, and adjustable spectrum, such that through the protective effect of the encapsulating material, not only the physical and optical stability of perovskite microsphere materials can be improved, but also an ion exchange between different halogen elements can be inhibited, thus maintaining the monochromaticity when the red and green perovskite materials are mixed. By using the red and green perovskite microspheres with the encapsulating structure provided by the present invention as an optical conversion material of the white OLED display, photon utilization of the organic light-emitting material can be improved, and display power consumption is reduced. Compared with a traditional light conversion layer of quantum dots, the optical conversion material of the red and green perovskite microspheres with the encapsulating structure can reduce hazards of heavy metals, and can narrow the spectrum, thereby improving the color purity and color gamut. Compared with a traditional evaporation white OLED, the optical conversion material of the red and green perovskite microspheres with the encapsulating structure greatly reduces the process difficulty and costs.

In order to achieve the above object, the present invention provides a perovskite microsphere material, including a plurality of perovskite microspheres, each of the plurality of perovskite microspheres including: of inorganic perovskite crystals as nucleus of the perovskite microsphere; and an amorphous silicon oxide spherical shell encapsulating the plurality of inorganic perovskite crystals, wherein the perovskite microspheres include green perovskite microspheres and red perovskite microspheres.

According to an embodiment of the present invention, a solution of the green perovskite microspheres has an emission peak at 515 nm to 525 nm in a fluorescence emission spectrum, and a full width at half maximum (FWHM) of the emission peak is 16 nm to 20 nm; and a solution of the red perovskite microspheres has an emission peak at 680 nm to 690 nm in a fluorescence emission spectrum, and a full width at half maximum (FWHM) of the emission peak is 32 nm to 37 nm.

According to an embodiment of the present invention, a method of preparing the perovskite microspheres includes the following steps:

S10 preparing a cesium oleate precursor;

S20 preparing a lead bromide precursor solution and a lead iodide precursor solution respectively; and

S30 mixing the lead bromide precursor solution with the cesium oleate precursor and silane to obtain the green perovskite microspheres; and mixing the lead iodide precursor solution with the cesium oleate precursor and silane to obtain the red perovskite microspheres.

According to an embodiment of the present invention, the step S10 includes:

S11: adding cesium carbonate and oleic acid to an octadecene solvent to obtain a mixed solution, wherein the cesium carbonate has a concentration of 20-25 mg/ml, and the oleic acid is present in an amount of 15-20% by weight; and

S12, purging nitrogen gas into the mixed solution followed by stirring at 100° C. to 140° C. until the cesium carbonate is completely dissolved into the cesium oleate precursor.

According to an embodiment of the present invention, the step S20 includes:

S21 dissolving PbBr2 and PbI2 respectively in an organic solvent to obtain the lead bromide precursor solution including 10-15 mg/ml of PbBr2, and the lead iodide precursor solution including 20-25 mg/ml of PbI2;

S22 purging nitrogen gas into the lead bromide precursor solution and the lead iodide precursor solution, followed by stirring at 100° C. to 140° C. for 40 minutes to 80 minutes, and then raising a temperature to 150° C. to 170° C.; and

S23 adding oleylamine and oleic acid (volume ratio 1:1) to the lead bromide precursor solution and the lead iodide precursor solution, followed by heating for 3-5 minutes until clear and transparent lead bromide and lead iodide precursor solutions are obtained.

According to an embodiment of the present invention, the step S30 includes:

S31 adding the cesium oleate precursor and the silane (volume ratio 4:5) to the lead bromide precursor solution and the lead iodide precursor solution to obtain a bright-colored colloid solution;

S32 heating and stirring the bright-colored colloidal solution for 5-8 minutes, followed by an ice bath to terminate the reaction; and

S33 centrifugally purifying the bright-colored colloidal solution, followed by low-temperature vacuum drying for 20-40 min, to obtain a dried perovskite powder, wherein the perovskite powder includes the green perovskite microspheres and the red perovskite microspheres.

According to an embodiment of the present invention, the silane is selected from the group consisting of tetraethyl orthosilicate, tetraoxysilane, triethoxysilane, methyltrimethoxysilane, and tetrapropoxysilane; and the organic solvent is octadecene

According to an embodiment of the present invention, the present invention also provides a mixed-color light conversion film, wherein the mixed-color light conversion film includes a light conversion layer, the light conversion layer includes a perovskite ultraviolet-curable (UV-curable) adhesive material, and the perovskite UV-curable adhesive material includes, based on 100 parts by weight of the perovskite UV-curable adhesive material: 5 to 10 parts by weight of the above-described red perovskite microspheres; 10 to 20 parts by weight of the above-described green perovskite microspheres; and 57 to 80 parts by weight of UV-curable glue, including: 35 to 45 parts by weight of resin, 20 to 25 parts by weight of ultraviolet light absorbing monomers, and 1 to 5 parts by weight of photoinitiators, and 1 to 5 parts by weight of diffusion particles.

According to an embodiment of the present invention, a method of preparing the mixed-color light conversion film includes:

S101 providing a first protective film and a second protective film, each independently made of a material including polyethylene terephthalate, and each independently having a thickness of 50 μm to 150 μm;

S102 performing vacuum-evaporation coating on a surface of the first protective film and a surface of the second protective film, so that the surface of the first protective film and the surface of the second protective film form a first barrier layer and a second barrier layer respectively, wherein each of the first barrier layer and the second barrier layer independently has a thicknesses of 2 μm to 5 μm;

S103 coating the perovskite UV-curable adhesive material on the first barrier layer;

S104 covering the second protective film on the perovskite UV-curable adhesive material, wherein the second barrier layer is disposed between the perovskite UV-curable adhesive material and the second protective film to obtain a mixed-color conversion film module; and

S105 UV-curing the mixed-color light conversion film module to obtain the mixed-color light conversion film.

According to an embodiment of the present invention, the present invention further provides a display, which is a white organic light-emitting diode display, including sequentially stacked: an anode; a hole injection layer; a hole transport layer; a blue light organic light-emitting layer; an electron transport layer; an electron injection layer; a cathode; and the above-described mixed-color light conversion film, wherein the mixed-color light conversion film includes: a first protective layer; a first barrier layer; the light conversion layer; a second barrier layer; and a second protective layer, which are sequentially stacked.

In the embodiment provided by the present invention, the blue light organic light-emitting layer emits excitation light to excite the perovskite UV-curable adhesive material in the light conversion layer to obtain photoluminescent red light and photoluminescent green light, which are mixed with blue light that is not absorbed by the ultraviolet light absorbing monomers to form white light.

An object of the present invention is to provide a white organic light-emitting diode (OLED) display with high stability. Therefore, the present invention develops red and green perovskite microspheres each with an encapsulating structure, which have advantages of a high light-emitting efficiency, narrow spectrum, and adjustable spectrum, such that through the protective effect of the encapsulating material, not only the physical and optical stability of perovskite microsphere materials can be improved, but also an ion exchange between different halogen elements can be inhibited, thus maintaining the monochromaticity when the red and green perovskite materials are mixed. By using the red and green perovskite microspheres with the encapsulating structure provided by the present invention as an optical conversion material of the white OLED display, photon utilization of the organic light-emitting material can be improved, and display power consumption is reduced. Compared with a traditional light conversion layer of quantum dots, the optical conversion material of the red and green perovskite microspheres with the encapsulating structure can reduce hazards of heavy metals, and can narrow the spectrum, thereby improving the color purity and color gamut. Compared with a traditional evaporation white OLED, the optical conversion material of the red and green perovskite microspheres with the encapsulating structure greatly reduces the process difficulty and costs.

### BRIEF DESCRIPTION OF DRAWINGS

In order to more clearly illustrate the embodiments or the technical solutions of the existing art, the drawings illustrating the embodiments or the existing art will be briefly described below. Obviously, the drawings in the following description merely illustrate some embodiments of the present invention. Other drawings may also be obtained by those skilled in the art according to these figures without paying creative work.

FIG. 1 is a schematic diagram of a perovskite microsphere material having an encapsulating structure in an embodiment of the present invention.

FIG. 2A is an emission spectrum of green perovskite microspheres.

FIG. 2B is an emission spectrum of red perovskite microspheres.

FIG. 3 is a schematic diagram of a mixed-color light conversion film according to an embodiment of the present invention.

FIG. 4 is a schematic diagram of a white organic light-emitting diode display according to an embodiment of the present invention.

FIG. 5 is a schematic principle diagram of a white organic light-emitting diode display according to an embodiment of the present invention.

### DETAILED DESCRIPTION OF PREFERRED EMBODIMENTS

In order to make the above description of the present invention more comprehensible, the preferred embodiments are described below in detail with reference to the accompanying drawings.

In the description of the present invention, it is to be understood that the terms “center”, “lateral”, “upper”, “lower”, “left”, “right”, “vertical”, “horizontal”, “top”, “bottom”, “inside”, “outside” and the like are based on the orientation or positional relationship shown in the drawings, and is merely for the convenience of describing the present invention and simplifying the description, and does not indicate or imply that the indicated devices or components must to be in particular orientations, or constructed and operated in a particular orientation, and thus are not to be construed as limiting the present invention. Furthermore, the terms “first”, “second”, etc. in the specification and claims of the present invention and the above figures are used to distinguish similar objects, and are not necessarily used to describe a specific order or prioritization. It should be understood that the objects so described are interchangeable when it is appropriate. Moreover, the terms “including” and “having” and any variations thereof are intended to cover a non-exclusive “inclusion”.

In the present invention, unless otherwise expressly stated and limited, the formation of a first feature over or under a second feature in the description that follows may include embodiments in which the first and second features are formed in direct contact, and may also include embodiments in which additional features may be formed between the first and second features, such that the first and second features may not be in direct contact. Moreover, the first feature “above”, “over” and “on” the second feature includes the first feature directly above and above the second feature, or merely indicating that the first feature is at a level higher than the second feature. The first feature “below”, “under” and “beneath” the second feature includes the first feature directly below and obliquely below the second feature, or merely the first feature has a level lower than the second feature.

An object of the present invention is to provide a white organic light-emitting diode (OLED) display with high stability. Therefore, the present invention develops red and green perovskite microspheres each with an encapsulating structure, which have advantages of a high light-emitting efficiency, narrow spectrum, and adjustable spectrum, such that through the protective effect of the encapsulating material, not only the physical and optical stability of perovskite microsphere materials can be improved, but also an ion exchange between different halogen elements can be inhibited, thus maintaining the monochromaticity when the red and green perovskite materials are mixed. By using the red and green perovskite microspheres with the encapsulating structure provided by the present invention as an optical conversion material of the white OLED display, photon utilization of the organic light-emitting material can be improved, and display power consumption is reduced. Compared with a traditional light conversion layer of quantum dots, the optical conversion material of the red and green perovskite microspheres with the encapsulating structure can reduce hazards of heavy metals, and can narrow the spectrum, thereby improving the color purity and color gamut. Compared with a traditional evaporation white OLED, the optical conversion material of the red and green perovskite microspheres with the encapsulating structure greatly reduces the process difficulty and costs.

To achieve the above object, the present invention provides a perovskite microsphere material, as shown in FIG. 1. FIG. 1 is a schematic diagram of a perovskite microsphere material having an encapsulating structure according to an embodiment of the present invention. As shown in FIG. 1, specifically, an embodiment of the present invention provides a perovskite microsphere material, including a plurality of perovskite microspheres 10, each of the plurality of perovskite microspheres 10 including a plurality of inorganic perovskite crystals 11 as nucleus of the perovskite microsphere 10; and an amorphous silicon oxide spherical shell 12 encapsulating the plurality of inorganic perovskite crystals 11, wherein the perovskite microspheres 10 include green perovskite microspheres 10G and red perovskite microspheres 10R, as shown in FIG. 3.

In the embodiment of the present invention, the light-emitting nucleus are all the inorganic perovskite crystals 11, and the protective shell layer is the transparent amorphous silicon oxide spherical shell 12. This encapsulating structure is used to isolate water and oxygen in the air and the solution and suppress ion exchange between different elements Br— and I— in perovskite, so as to maintain monochromaticity of the perovskite material.

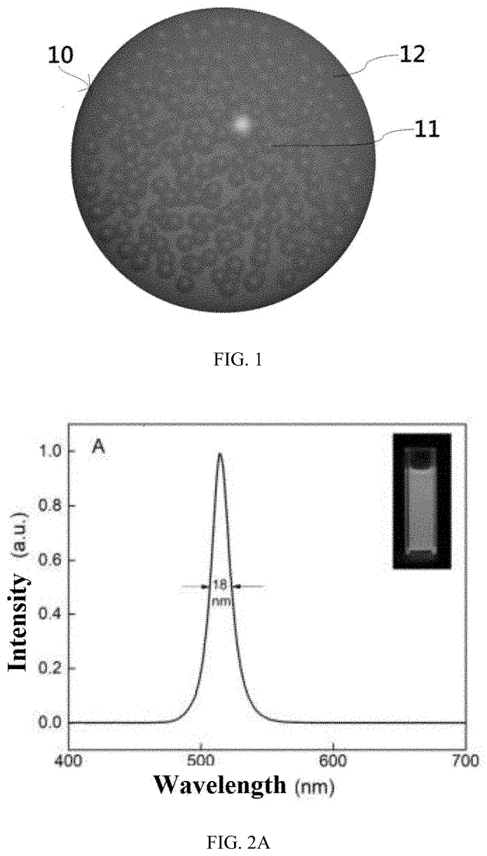

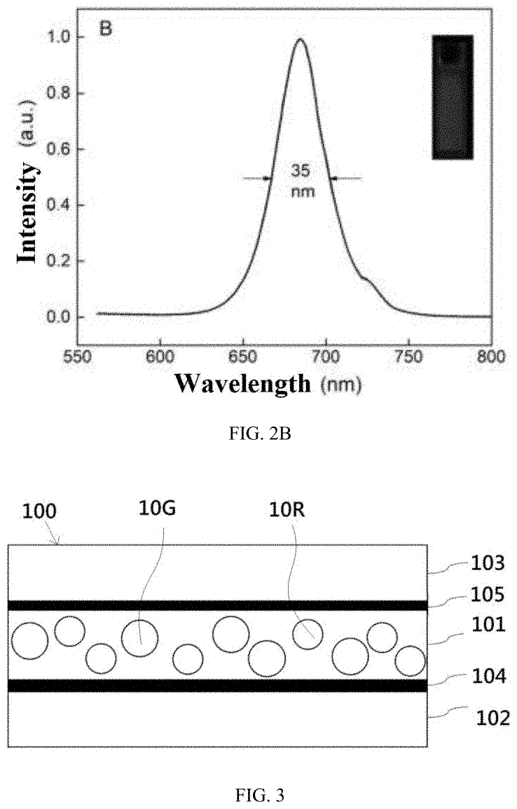

FIG. 2A is an emission spectrum of green perovskite microspheres. FIG. 2B is an emission spectrum of red perovskite microspheres. Referring to FIG. 2A and FIG. 2B, according to an embodiment of the present invention, a solution of the green perovskite microspheres 10G has an emission peak at 515 nm to 525 nm in a fluorescence emission spectrum, and a full width at half maximum (FWHM) of the emission peak is 16 nm to 20 nm; and a solution of the red perovskite microspheres 10R has an emission peak at 680 nm to 690 nm in a fluorescence emission spectrum, and a full width at half maximum (FWHM) of the emission peak is 32 nm to 37 nm.

As shown in FIG. 2A and FIG. 2B, further, in a specific embodiment of the present invention, the solution of the green perovskite microspheres 10G has an emission peak at 520 nm in a fluorescence emission spectrum, and a full width at half maximum (FWHM) of the emission peak is 18 nm; and the solution of the red perovskite microspheres 10R has an emission peak at 684 nm in a fluorescence emission spectrum, and a full width at half maximum (FWHM) of the emission peak is 35 nm.

In the embodiment of the present invention, the method of preparing the green and red perovskite microsphere is thermal injection. The synthesized perovskite material has a narrower emission spectrum than the organic light-emitting material, and has a high emission fluorescence brightness under ultraviolet light, as shown in FIG. 2A and FIG. 2B.

The present invention also provides a method of preparing the perovskite microspheres, including the following steps:

S10 preparing a cesium oleate precursor;

S20 preparing a lead bromide precursor solution and a lead iodide precursor solution respectively; and

S30 mixing the lead bromide precursor solution with the cesium oleate precursor and silane to obtain the green perovskite microspheres 10G; and mixing the lead iodide precursor solution with the cesium oleate precursor and silane to obtain the red perovskite microspheres 10R.

According to an embodiment of the present invention, the step S10 includes:

S11 adding cesium carbonate and oleic acid to an octadecene solvent to obtain a mixed solution, wherein the cesium carbonate has a concentration of 20-25 mg/ml, and the oleic acid is present in an amount of 15-20% by weight; and

S12 purging nitrogen gas into the mixed solution followed by stirring at 100° C. to 140° C. until the cesium carbonate is completely dissolved into the cesium oleate precursor.

According to an embodiment of the present invention, the step S20 includes:

S21 dissolving PbBr2 and PbI2 respectively in an organic solvent to obtain the lead bromide precursor solution including 10-15 mg/ml of PbBr2, and the lead iodide precursor solution including 20-25 mg/ml of PbI2;

S22 purging nitrogen gas into the lead bromide precursor solution and the lead iodide precursor solution, followed by stirring at 100° C. to 140° C. for 40 minutes to 80 minutes, and then raising a temperature to 150° C. to 170° C.; and

S23 adding oleylamine and oleic acid (volume ratio 1:1) to the lead bromide precursor solution and the lead iodide precursor solution, followed by heating for 3-5 minutes until clear and transparent lead bromide and lead iodide precursor solutions are obtained.

According to an embodiment of the present invention, the step S30 includes:

S31 adding the cesium oleate precursor and the silane (volume ratio 4:5) to the lead bromide precursor solution and the lead iodide precursor solution to obtain a bright-colored colloid solution;

S32 heating and stirring the bright-colored colloidal solution for 5-8 minutes, followed by an ice bath to terminate the reaction; and

S33 centrifugally purifying the bright-colored colloidal solution, followed by low-temperature vacuum drying for 20-40 min, to obtain a dried perovskite powder, wherein the perovskite powder includes the green perovskite microspheres 10G and the red perovskite microspheres 10R.

According to an embodiment of the present invention, the silane is selected from the group consisting of tetraethyl orthosilicate, tetraoxysilane, triethoxysilane, methyltrimethoxysilane, and tetrapropoxysilane; and the organic solvent is octadecene.

Further, in a specific embodiment of the present invention, a method of preparing the perovskite microspheres with the encapsulating structure is thermal injection, which includes the following steps:

S10 preparing a cesium oleate precursor: adding CsCO3 and oleic acid a to an octadecene solvent to obtain a mixed solution, wherein the cesium carbonate is present in a concentration of 20-25 mg/ml, and the oleic acid is present in an amount of 15-20% by weight; and then, purging nitrogen gas into the mixed solution followed by magnetic stirring at 120° C. for 1 hour, until the cesium carbonate is completely dissolved into the cesium oleate precursor.

S20 preparing a lead bromide precursor solution and a lead iodide precursor solution respectively: dissolving PbBr2 and PbI2 respectively in an organic solvent to obtain the lead bromide precursor solution including 10-15 mg/ml of PbBr2, and the lead iodide precursor solution including 20-25 mg/ml of PbI2; then purging nitrogen gas into the lead bromide precursor solution and the lead iodide precursor solution, followed by magnetic stirring at 120° C. for 1 hour, and then raising a temperature to 150° C. to 170° C.; and finally adding oleylamine and oleic acid (volume ratio 1:1) to the lead bromide precursor solution and the lead iodide precursor solution, followed by heating for 3-5 minutes until clear and transparent lead bromide and lead iodide precursor solutions are obtained.

S30: mixing the lead bromide precursor solution with the cesium oleate precursor and silane to obtain the green perovskite microspheres; and mixing the lead iodide precursor solution with the cesium oleate precursor and silane to obtain the red perovskite microspheres: directly adding the cesium oleate precursor and the silane (volume ratio 4:5) to the lead bromide precursor solution and the lead iodide precursor solution to obtain a bright-colored colloid solution; then heating and magnetically stirring the bright-colored colloidal solution for 5-8 minutes, then stopping stirring, followed by an ice bath to terminate the reaction, and so far the green and red perovskite microspheres with the encapsulating materials have been synthesized; and finally centrifugally purifying the bright-colored colloidal solution, followed by low-temperature vacuum drying for 30 min, to obtain a dried perovskite powder, wherein the perovskite powder includes the green perovskite microspheres and the red perovskite microspheres.

According to an embodiment of the present invention, the present invention also provides a mixed-color light conversion film, as shown in FIG. 3. FIG. 3 is a schematic diagram of a mixed-color light conversion film according to an embodiment of the present invention. As shown in FIG. 3, specifically, an embodiment of the present invention provides a mixed-color light conversion film 100, wherein the mixed-color light conversion film 100 includes a light conversion layer 101, the light conversion layer 101 includes a perovskite ultraviolet-curable (UV-curable) adhesive material, and the perovskite UV-curable adhesive material includes, based on 100 parts by weight of the perovskite UV-curable adhesive material: 10 to 40 parts by weight of the red perovskite microspheres 1 OR and the green perovskite microspheres; and 60 to 90 parts by weight of UV-curable glue.

Still referring to FIG. 3, according to an embodiment of the present invention, the present invention further provides a method of preparing the mixed-color light conversion film 100, including:

S101 providing a first protective film 102 and a second protective film 103, each independently made of a material including polyethylene terephthalate, and each independently having a thickness of 50 μm to 150 μm;

S102 performing vacuum-evaporation coating on a surface of the first protective film 102 and a surface of the second protective film 103, so that the surface of the first protective film 102 and the surface of the second protective film 103 form a first barrier layer 104 and a second barrier layer 105 respectively, wherein each of the first barrier layer 104 and the second barrier layer 105 independently has a thicknesses of 2 μm to 5 μm;

S103 coating the perovskite UV-curable adhesive material on the first barrier layer 104;

S104 covering the second protective film 103 on the perovskite UV-curable adhesive material, wherein the second barrier layer 105 is disposed between the perovskite UV-curable adhesive material and the second protective film 103 to obtain a mixed-color conversion film module; and

S105 UV-curing the mixed-color light conversion film module to obtain the mixed-color light conversion film 100.

Further, in a specific embodiment of the present invention, the method of preparing the mixed-color light conversion film 100 includes the following steps S1001 to S1003:

S1001 formulating a mixed solution of the prepared green and red perovskite microsphere powder and UV-curable glue, wherein the perovskite powder is present in an amount of 10-40% of a total weight of the mixed solution, and components of the UV-curable glue include resin, monomers, photoinitiators, and diffusion particles; and then stirring the mixed solution uniformly to obtain a red-green mixed-color perovskite glue, wherein the green and red perovskite microsphere materials are stably present in a form of homogeneous nanoparticles in the UV-curable glue, which provides good film formation for the mixed perovskite microsphere materials.

Further, in the step S1001 according to a specific embodiment of the present invention, based on 100 parts by weight of the perovskite UV-curable adhesive material, the perovskite UV-curable adhesive material includes: 5 to 10 parts by weight of the red perovskite microspheres according to claims 1; 10 to 20 parts by weight of the green perovskite microspheres according to claim 1; and 57 to 80 parts by weight of UV-curable glue, including: 35 to 45 parts by weight of resin, 20 to 25 parts by weight of ultraviolet light absorbing monomers, and 1 to 5 parts by weight of photoinitiators, and 1 to 5 parts by weight of diffusion particles.

S1002 using polyethylene terephthalate (PET) as materials of the first protective film 102 and the second protective film 103 (both having thicknesses ranging from 50 μm to 150 μm), performing vacuum evaporation coating on front surfaces of PET films of the first protective film 102 and second protective film 103 to form thereon the first barrier layer 104 and the second barrier layer 105 (both having thicknesses ranging from about 2 μm to 5 μm), which have good water and oxygen blocking performance.

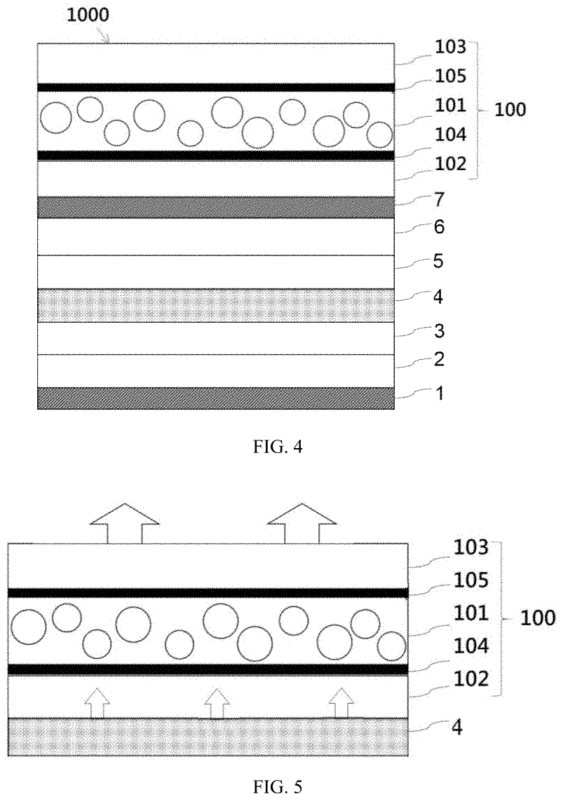

S1003 applying the prepared red-green perovskite mixed glue on the first barrier layer 103; covering red-green perovskite mixed glue with the second protective film 103; then obtaining the red-green mixed-color light conversion film after ultraviolet curing, as shown in FIG. 3; and finally, covering a light-exiting surface of a blue OLED with the prepared red-green mixed-color light conversion film, thus constituting a white OLED provided in the following embodiments, as shown in FIG. 4.

According to an embodiment of the present invention, the present invention further provides a white organic light-emitting diode display, as shown in FIG. 4. FIG. 4 is a schematic diagram of a white organic light-emitting diode display according to an embodiment of the present invention. As shown in FIG. 4, in particular, an embodiment of the present invention further provides a white organic light-emitting diode display 1000 including: an anode 1; a hole injection layer 2; a hole transport layer 3, a blue light organic light-emitting layer 4; an electron transport layer 5; an electron injection layer 6; a cathode 7; and the mixed-color light conversion film 100 according to the present invention, which are sequentially stacked, wherein the mixed-color light conversion film 100 includes: a first protective layer 102, a first barrier layer 104, the light conversion layer 101, a second barrier layer 105, and a second protective layer 103, which are sequentially stacked.

FIG. 5 is a schematic principle diagram of a white organic light-emitting diode display 1000 according to an embodiment of the present invention. As shown in FIG. 5, in the embodiment provided by the present invention, the blue light organic light-emitting layer 4 emits excitation light to excite the perovskite UV-curable adhesive material in the light conversion layer 101 to obtain photoluminescent red light and photoluminescent green light, which are mixed with blue light that is not absorbed by the ultraviolet light absorbing monomers to form white light.

According to other embodiments of the present invention, a light-emitting source of the blue light-emitting layer may be selected from the group consisting of: a blue organic light-emitting diode, a blue light chip, and a micro light-emitting diode (micro-LED).

According to other embodiments of the present invention, the perovskite microsphere material may be: all-inorganic perovskite material or an organic-inorganic hybrid perovskite material.

Accordingly, the present invention provides a perovskite microsphere material, a mixed-color light conversion film, preparation methods thereof, and a display. By developing the red and green perovskite microspheres each with an encapsulating structure, which have advantages of a high light-emitting efficiency, narrow spectrum, and adjustable spectrum, through the protective effect of the encapsulating material, not only the physical and optical stability of perovskite microsphere materials can be improved, but also an ion exchange between different halogen elements can be inhibited, thus maintaining the monochromaticity when the red and green perovskite materials are mixed. By using the red and green perovskite microspheres with the encapsulating structure provided by the present invention as an optical conversion material of the white OLED display, photon utilization of the organic light-emitting material can be improved, and display power consumption is reduced. Compared with a traditional light conversion layer of quantum dots, the optical conversion material of the red and green perovskite microspheres with the encapsulating structure can reduce hazards of heavy metals, and can narrow the spectrum, thereby improving the color purity and color gamut. Compared with a traditional evaporation white OLED, the optical conversion material of the red and green perovskite microspheres with the encapsulating structure greatly reduces the process difficulty and costs.

While the present invention has been described by way of example and in terms of the preferred embodiments, it is to be understood that the present invention is not limited to the disclosed embodiments. To the contrary, it is intended to cover various modifications and similar arrangements. Therefore, the scope of the appended claims should be accorded the broadest interpretation so as to encompass all such modifications and similar arrangements.

What is claimed is:

1. A perovskite microsphere material, comprising a plurality of perovskite microspheres, each of the plurality of perovskite microspheres comprising:
a plurality of inorganic perovskite crystals as nucleus of the perovskite microsphere; and
an amorphous silicon oxide spherical shell encapsulating the plurality of inorganic perovskite crystals,
wherein the perovskite microspheres comprise green perovskite microspheres and red perovskite microspheres.

2. The perovskite microsphere material according to claim 1, wherein a solution of the green perovskite microspheres has an emission peak at 515 nm to 525 nm in a fluorescence emission spectrum, and a full width at half maximum (FWHM) of the emission peak is 16 nm to 20 nm; and a solution of the red perovskite microspheres has an emission peak at 680 nm to 690 nm in a fluorescence emission spectrum, and a full width at half maximum (FWHM) of the emission peak is 32 nm to 37 nm.

3. The perovskite microsphere material according to claim 1, wherein a method of preparing the perovskite microspheres comprises the following steps:
S10 preparing a cesium oleate precursor;
S20 preparing a lead bromide precursor solution and a lead iodide precursor solution respectively; and
S30 mixing the lead bromide precursor solution with the cesium oleate precursor and silane to obtain the green perovskite microspheres; and mixing the lead iodide precursor solution with the cesium oleate precursor and silane to obtain the red perovskite microspheres.

4. The perovskite microsphere material according to claim 3, wherein the step S10 comprises:
S11: adding cesium carbonate and oleic acid to an octadecene solvent to obtain a mixed solution, wherein the cesium carbonate has a concentration of 20-25 mg/ml, and the oleic acid is present in an amount of 15-20% by weight; and
S12, inserting nitrogen gas into the mixed solution followed by stirring at 100° C. to 140° C. until the cesium carbonate is completely dissolved into the cesium oleate precursor.

5. The perovskite microsphere material according to claim 3, wherein the step S20 comprises:
S21 dissolving PbBr2 and PbI2 respectively in an organic solvent to obtain the lead bromide precursor solution comprising 10-15 mg/ml of PbBr2, and the lead iodide precursor solution comprising 20-25 mg/ml of PbI2;
S22 purging nitrogen gas into the lead bromide precursor solution and the lead iodide precursor solution, followed by stirring at 100° C. to 140° C. for 40 minutes to 80 minutes, and then raising a temperature to 150° C. to 170° C.; and
S23 adding oleylamine and oleic acid (volume ratio 1:1) to the lead bromide precursor solution and the lead iodide precursor solution, followed by heating for 3-5 minutes until clear and transparent lead bromide and lead iodide precursor solutions are obtained.

6. The perovskite microsphere material according to claim 3, wherein the step S30 comprises:
S31 adding the cesium oleate precursor and the silane (volume ratio 4:5) to the lead bromide precursor solution and the lead iodide precursor solution to obtain a bright-colored colloid solution;
S32 heating and stirring the bright-colored colloidal solution for 5-8 minutes, followed by an ice bath to terminate the reaction; and
S33 centrifugally purifying the bright-colored colloidal solution, followed by low-temperature vacuum drying for 20-40 min, to obtain a dried perovskite powder, wherein the perovskite powder comprises the green perovskite microspheres and the red perovskite microspheres.

7. The perovskite microsphere material according to claim 3, wherein the silane is selected from the group consisting of tetraethyl orthosilicate, tetraoxysilane, triethoxysilane, methyltrimethoxysilane, and tetrapropoxysilane; and the organic solvent is octadecene.

8. A mixed-color light conversion film, wherein the mixed-color light conversion film comprises a light conversion layer, the light conversion layer comprises a perovskite ultraviolet-curable (UV-curable) adhesive material, and the perovskite UV-curable adhesive material comprises, based on 100 parts by weight of the perovskite UV-curable adhesive material:
5 to 10 parts by weight of the red perovskite microspheres according to claim 1;
10 to 20 parts by weight of the green perovskite microspheres according to claim 1; and
57 to 80 parts by weight of UV-curable glue, comprising: 35 to 45 parts by weight of resin, 20 to 25 parts by weight of ultraviolet light absorbing monomers, and 1 to 5 parts by weight of photoinitiators, and 1 to 5 parts by weight of diffusion particles.

9. The mixed-color light conversion film according to claim 8, wherein a method of preparing the mixed-color light conversion film comprises:
S101 providing a first protective film and a second protective film, each independently made of a material comprising polyethylene terephthalate, and each independently having a thickness of 50 μm to 150 μm;
S102 performing vacuum-evaporation coating on a surface of the first protective film and a surface of the second protective film, so that the surface of the first protective film and the surface of the second protective film form a first barrier layer and a second barrier layer respectively, wherein each of the first barrier layer and the second barrier layer independently has a thicknesses of 2 μm to 5 μm;
S103 coating the perovskite UV-curable adhesive material on the first barrier layer;
S104 covering the second protective film on the perovskite UV-curable adhesive material, wherein the second barrier layer is disposed between the perovskite UV-curable adhesive material and the second protective film to obtain a mixed-color conversion film module; and
S105 UV-curing the mixed-color light conversion film module to obtain the mixed-color light conversion film.

10. A display, which is a white organic light-emitting diode display, comprising sequentially stacked:
an anode;
a hole injection layer;
a hole transport layer;
a blue light organic light-emitting layer;
an electron transport layer;
an electron injection layer;
a cathode; and
the mixed-color light conversion film according to claim 8,
wherein the mixed-color light conversion film comprises: a first protective layer; a first barrier layer; the light conversion layer; a second barrier layer; and a second protective layer, which are sequentially stacked, and
wherein the blue light organic light-emitting layer emits excitation light to excite the perovskite UV-curable adhesive material in the light conversion layer to obtain photoluminescent red light and photoluminescent green light, which are mixed with blue light that is not absorbed by the ultraviolet light absorbing monomers to form white light.
